(19) United States
(12) Patent Application Publication
(10) Pub. No.: US 2013/0078761 A1
(43) Pub. Date: Mar. 28, 2013

(54) METHOD FOR MANUFACTURING A FLEXIBLE TRANSPARENT 1T1R STORAGE UNIT BASED ON A COMPLETELY LOW-TEMPERATURE PROCESS

(71) Applicants: Qingqing Sun, Shanghai (CN); Runchen Fang, Shanghai (CN); Wen Yang, Shanghai (CN); Pengfei Wang, Shanghai (CN); Wei Zhang, Shanghai (CN)

(72) Inventors: Qingqing Sun, Shanghai (CN); Runchen Fang, Shanghai (CN); Wen Yang, Shanghai (CN); Pengfei Wang, Shanghai (CN); Wei Zhang, Shanghai (CN)

(21) Appl. No.: 13/528,462

(22) Filed: Jun. 20, 2012

(30) Foreign Application Priority Data
Sep. 23, 2011 (CN) CN201110285132.X

(51) Int. Cl. H01L 21/336

(52) U.S. Cl. 438/104; 257/E21.411

(57) ABSTRACT

The present invention belongs to the technical field of low temperature atomic layer deposition technology, and specifically relates to a method for manufacturing a flexible transparent 1T1R storage unit. In the present invention, a fully transparent 1T1R storage unit is developed on a flexible substrate through a completely low-temperature process, including an oxide layer dielectric, a transparent electrode and a transparent substrate which are deposited together through a low-temperature process, thus realizing a fully transparent device capable of achieving the functions of nontransparent devices. The present invention can be applied to the manufacturing of flexible low-temperature storage units in the future, as well as changing the packaging and existing modes of devices, which will make foldable and bendable portable storage units possible.

### CROSS-REFERENCE TO RELATED APPLICATION

This application is a continuation of and claims priority to Chinese Patent Application No. CN201110285132.X filed on Sep. 23, 2011, the entire content of which is incorporated by reference herein.

### BACKGROUND OF THE INVENTION

1. Technical Field

The present invention belongs to the technical field of low-temperature atomic layer deposition (ALD), relates to a method for manufacturing resistive random access memory (RRAM) and thin-film transistors (TFT), and more especially, relates to a low-temperature manufacturing method for transparent RRAM and TFT on a flexible substrate.

2. Description of Related Art

The traditional 1T1R (one transistor/one resistor) structure with a substrate made of hard substrate materials, such as silicon, using visible substances are widely used in the 3memory devices and non-volatile memory devices, so the principle and technology of this structure is quite mature and has already been applied.

Flexible memory devices can be used in the manufacturing of non-volatile memory devices in the future and it is possible to replace the current hard memory devices with a silicon substrate in the future because of its cost effectiveness. Moreover, flexible memories are easier to fold and bend, making them more convenient to carry and capable of existing in more variable modes and being manufactured on the surface of any flexible substance, such as the surface of plastic food cans and packages.

Since the substrate of most flexible memories are of flexible plastic, and the heat-resistance temperature of most kinds of plastics are below 100□, even for some kinds of special plastic, the temperature can not exceed 400□, in view of this, the completely low-temperature process must be used when realizing flexible memories. In order to realize this process, the electrodes, oxide layers, and some dielectric layers must be developed through physical vapor deposition (PVD) method, low-temperature ADL method, or spin-coating method. For the sake of adapting to the miniaturization trend of devices, the thickness of the electrodes must be about 20 nm and that of the oxide layer must be about 10 nm.

The traditional TFT processes are quite mature and most of them use hydrogenated amorphous silicon as the main substrate material, so most of the TFT are nontransparent. However, they are widely used in the display field. The TFT manufacturing process is simple and can be realized by repeatedly depositing different films on the substrate, so it can be produced in batches with small size.

### BRIEF SUMMARY OF THE INVENTION

In view of this, the present invention aims at putting forward a method for manufacturing 1T1R structures based on flexible substrates and the TFT process, thus changing the current packaging and existing modes of devices, and further making the foldable and bendable portable storage unit possible.

The method for manufacturing a flexible transparent 1T1R storage unit provided by the present invention includes the following steps:

provide a flexible substrate;

form a gate electrode on the flexible substrate;

cover the gate electrode to form a gate oxide layer;

form a transparent oxide channel on the gate oxide layer;

form a source and a drain electrode on both sides of the oxide channel;

form an oxide resistive storage layer on the drain electrode;

form a top-electrode on the oxide resistive storage layer.

Further, the flexible substrate is formed from organic polymers such as polyethylene terephthalate (PET), polyimide (PI), metal or ceramic materials. The gate oxide layer is formed of silicon dioxide, silicon nitride or other high dielectric constant materials. The transparent oxide channel is formed from ZnO or ZnInSnO, etc. The oxide resistive storage layer is formed of TiO₂, ZrO₂, SrTiO₃ or Al₂O₃, etc.

Furthermore, the gate electrode is formed from indium oxide (ITO) doped with tin. The source & drain electrodes and the top-electrode are formed of materials such as ITO or ZnO doped with Al or In.

The present invention, developing fully transparent 1T1R storage units on a flexible substrate through a completely low-temperature, includes a transparent oxide layer dielectric, a transparent electrode and a transparent substrate which are deposed together through low-temperature, thus realizing a fully transparent device capable of realizing the functions of non-transparent devices.

The method for manufacturing a flexible transparent 1T1R storage unit provided by the present invention features the following advantages:

1. the fully transparent 1T1R storage unit made with a flexible substrate is not only environmentally-friendly, but also manufacturing cost-saving, and can adapt to environmental devices in the future; moreover, since the devices are fully transparent, they can be manufactured on transparent substances through a transparent packaging process, thus really realizing portable storage;

2. the production using totally low-temperature process requires no heating and heat dissipation, thus reducing energy consumption as well as saving the total manufacturing time;

3. use a TFT to replace the field effect transistor (FET) as a part of the storage unit, which can adapt to the miniaturization trend of devices; in addition, the cost can be saved due to the simple TFT manufacturing process;

4. the present invention is capable of being applied to the manufacturing of flexible low-temperature storage units in the future as well as changing the current packaging and existing modes of devices, and makes the foldable and bendable portable storage unit possible.

### BRIEF DESCRIPTION OF THE SEVERAL VIEWS OF THE DRAWINGS

FIG. 1 is the sectional view of an embodiment of a fully transparent 1T1R storage unit provided by the present invention.

FIGS. 2-8 are the process flow diagrams of the embodiments of a method provided by the present invention for manufacturing the 1T1R storage unit as shown in FIG. 1.

### DETAILED DESCRIPTION OF THE INVENTION

An exemplary embodiment of the present invention is further detailed herein by referring to the drawings. In the drawings, the thicknesses of the layers and regions are either zoomed in or out for the convenience of description, so they shall not be considered as the true size. The reference diagrams are the schematic diagrams, but they shall not be considered as a limit to the scope of the present invention. Meanwhile, the term “substrate” used in the following description can be considered as a semiconductor substrate during manufacturing process, and other film layers prepared on it may also be included.

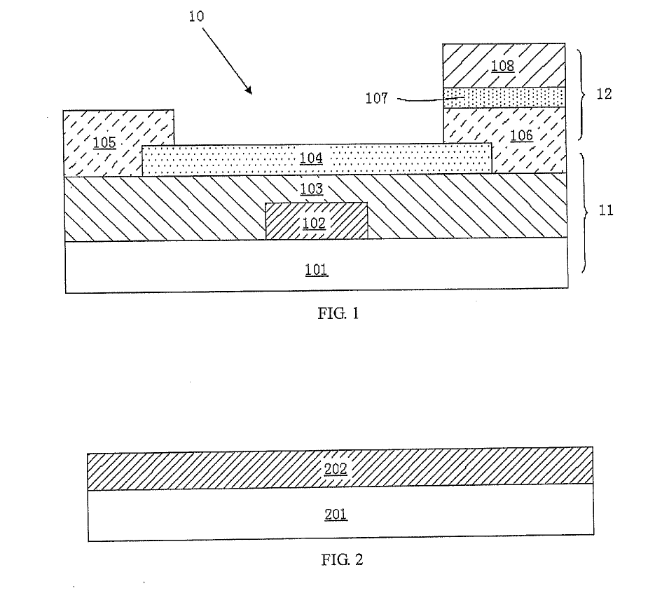

FIG. 1 is the sectional view of an embodiment of a fully transparent 1T1R storage unit provided by the present invention. As shown in FIG. 1, the 1T1R storage unit 10 is formed on a flexible substrate 101, including a TFT part 11 and an RRAM part 12. The TFT part includes a gate electrode 102, a gate oxide layer 103, an oxide channel layer 104, a source electrode 105 and a drain electrode 106 which are located on both sides of the oxide channel layer 103. The RRAM part uses the drain electrode 106 of the TFT 11 as bottom-electrode and includes an oxide resistive storage layer 107 and a top-electrode 108 formed on the bottom-electrode 106.

The fully transparent 1T1R storage unit as shown in FIG. 1 provided by the present invention can be manufactured through many methods and the description below is an embodiment of the method disclosed by the present invention for manufacturing a fully transparent 1T1R storage unit as shown in FIG. 1.

Although these drawings cannot accurately reflect the true size of the device, they still reflect the relative positions among the regions and composition structures completely, especially the up-down and adjacent relations.

Firstly, prepare a solution with NaOH and water in proportion of 1:20, heat it to 80□, immerse and rinse a polymide (P1) substrate with the solution for 20 min. Then immerse the P1 substrate in the isopropyl alcohol solution and conduct ultrasonic washing for 10 min. Finally, put the P1 substrate into deionized water, conduct ultrasonic washing for 10 min and blow-dry the P1 substrate surface with N2.

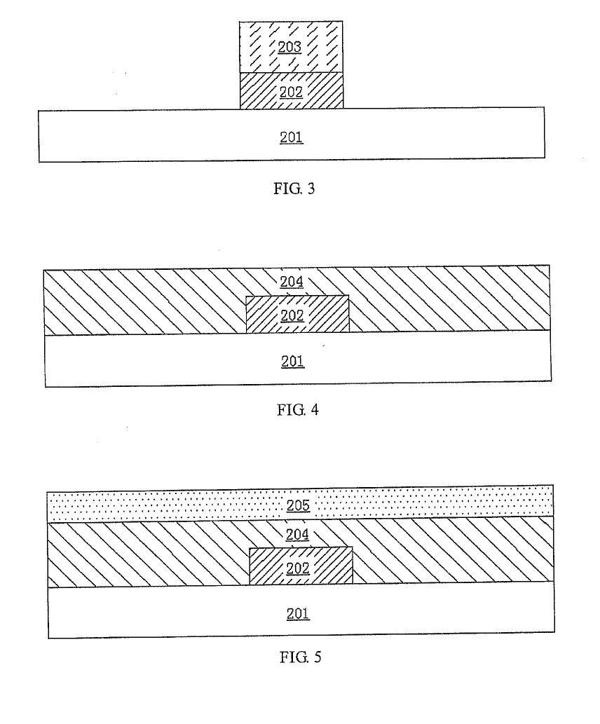

Next, develop an ITO layer 202 with a thickness of 20 nm on the surface of the PI substrate 201 treated through the PVD method and then deposit a layer of photoresist 203, as shown in FIG. 2. Next, soft-bake the base plate on a hot plate of 90□ for 30 s, then expose it to a UV light source, post-bake it on a hot plate of 100□, develop it to form a pattern, and finally etch the ITO layer 202 to form a gate electrode, as shown in FIG. 3.

After removing the photoresist 203, develop a layer of silicon dioxide with a thickness of 10 nm from a silicon target on the surface of the base plate in the presence of oxygen through the PVD method, then form a gate oxide layer 204 after flattening it, as shown in FIG. 4.

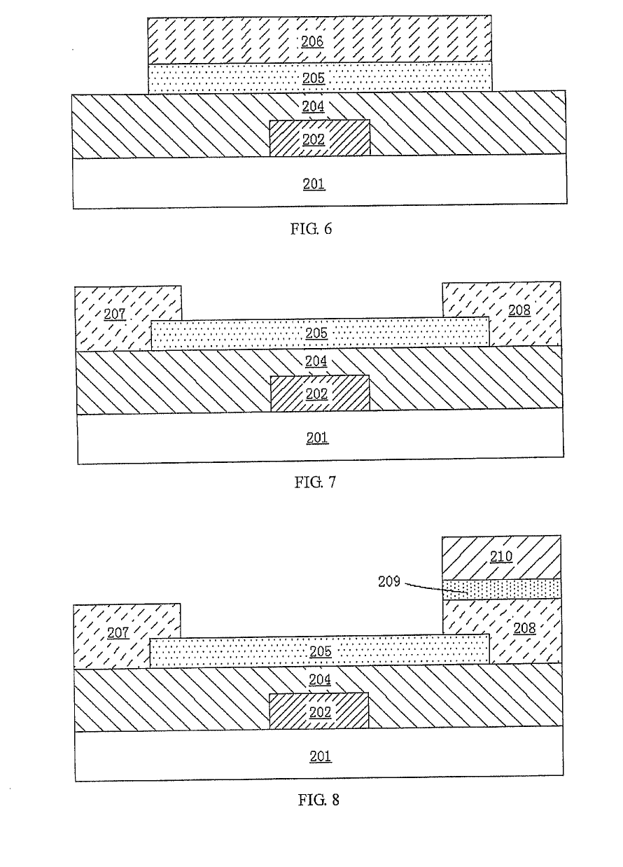

Next, develop a layer of ZnO film 205 having a thickness of 20 nm and a width the same with that of the PI substrate 201 with diethylzinc (DEZn) and water as the reaction precursor at room temperature and an air pressure of 10 mbar through the low-temperature ALD method, as shown in FIG. 5. Next, form a layer of photoresist 206 through spin-coating, then form a pattern again through photoetching and etch the ZnO film 205 to form a conductive channel, as shown in FIG. 6.

After the photoresist 206, prepare the channel surface through PVD sputtering, deposit a layer of transparent ZnO conductive layer with a thickness of 100 nm and form a source electrode 207 and a drain electrode 208 after the processes such as the spin-coating of the photoresist, formation of a pattern through photoetching, the etching and flattening, as shown in FIG. 7.

Finally, fix a hardmask on the base plate, develop an Al₂O₃ film with a thickness of 10 nm on the surface of the drain electrode 208 at a temperature of 100° C. and a pressure of 3 mbar through the low-temperature ALD method, as a resistive storage layer 209, then develop a layer of AZO (ZnO doped with Al) having a thickness of 20-30 nm with an aluminum target and a zinc target in the presence of oxygen using the PVD method through sputtering as a top-electrode 210 and take off the hardmask after the development, as shown in FIG. 8, thus finishing the manufacturing of a fully transparent 1T1R storage unit.

As described above, without deviating from the spirit and scope of the present invention, there may be many significantly different embodiments. It shall be understood that the present invention is not limited to the specific embodiments described in the Specification except those limited by the Claims herein.

What is claimed is:

1. A method for manufacturing a flexible transparent 1T1R storage unit, characterized in that it includes the following steps:
provide a flexible substrate;
form a gate electrode on the flexible substrate;
cover the gate electrode to form a gate oxide layer;
form a transparent oxide channel on the gate oxide layer;
form a source and drain electrodes on both sides of the oxide channel;
form an oxide resistive storage layer on the drain electrode;
form a top-electrode on the oxide resistive storage layer.

2. The method for manufacturing a flexible transparent 1T1R storage unit according to claim 1, characterized in that the flexible substrate is formed from polyethylene terephthalate, polyimide, metal or ceramic materials.

3. The method for manufacturing a flexible transparent 1T1R storage unit according to claim 1, characterized in that the gate electrode is formed from indium oxide doped with tin.

4. The method for manufacturing a flexible transparent 1T1R storage unit according to claim 1, characterized in that the gate oxide layer is formed from silicon dioxide, silicon nitride and other high dielectric constant materials.

5. The method for manufacturing a flexible transparent 1T1R storage unit according to claim 1, characterized in that the transparent oxide channel is formed from ZnO or ZnInSnO materials.

6. The method for manufacturing a flexible transparent 1T1R storage unit according to claim 1, characterized in that the source and drain electrodes are formed from ITO or ZnO materials doped with Al or In.

7. The method for manufacturing a flexible transparent 1T1R storage unit according to claim 1, characterized in that the oxide resistive storage layer is formed from TiO₂, ZrO₂, SrTiO₃ or Al₂O₃ materials.

8. The method for manufacturing a flexible transparent 1T1R storage unit according to claim 1, characterized in that the top-electrode is formed from ITO or ZnO materials doped with Al or In.
